(19) United States
(12) Patent Application Publication
(10) Pub. No.: US 2025/0234428 A1
(43) Pub. Date: Jul. 17, 2025

(54) SUBSTRATE PROCESSING APPARATUS

(71) Applicant: YEST CO., LTD., Pyeongtaek-si (KR)

(72) Inventors: Young Joon Ham, Pyeongtaek-si (KR); Jeong Eui Kim, Incheon (KR); Yong Hwan Kwon, Yongin-si (KR); Jin Seok Lee, Pyeongtaek-si (KR); Jong Hwan Baek, Pyeongtaek-si (KR); Byung Wook Hwang, Anseong-Si (KR); Yeon Min Mo, Pyeongtaek-si (KR)

(21) Appl. No.: 18/824,671

(22) Filed: Sep. 4, 2024

(30) Foreign Application Priority Data
Jan. 15, 2024 (KR) 10-2024-0005895

(51) Int. Cl. H05B 3/02; H01L 21/67

(52) U.S. Cl. CPC H05B 3/02; H01L 21/67109

(57) ABSTRACT

A substrate processing apparatus includes a chamber, a chamber door, an outer chamber, and a locking mechanism, in which the chamber door includes a first flange on which a substrate loader or a lower heater accommodating the substrate is placed, a rotating flange rotatably connected to the first flange, and a second flange disposed below the first flange and rotatably connected to the rotating flange.

### CROSS-REFERENCE TO RELATED APPLICATIONS

This application claims the priority benefit of Korean Patent Application No. 10-2024-0005895, filed on Jan. 15, 2024, in the Korean Intellectual Property Office, the entire disclosure of which is incorporated herein by reference for all purposes.

### FIELD OF THE DISCLOSURE

One or more embodiments relate to a substrate processing apparatus.

### BACKGROUND

High-pressure heat treatment of a semiconductor wafer is not only essential for manufacturing a static random-access memory (SRAM) chip by 45 nanometers (nm) process technology, which is next-generation semiconductor technology, but is also effective in increasing the driving speed and lifespan of various conventional chips. This is original technology developed in Korea and expected to play an important role in pioneering overseas markets.

As prior patents related to heat treatment of a semiconductor wafer, Korean Patent

Application Publication No. 2011-0049397 ([0003] Prior Patent 1), Korean Patent Application Publication No. 2013-0110014 (Prior Patent 2), etc. are known.

Prior Patent 1 discloses forming a first oxide film on a semiconductor substrate, forming a silicon nitride film on the first oxide film, converting the silicon nitride film into a silicon-rich silicon nitride film by performing a high-pressure hydrogen heat treatment process, and sequentially forming a second oxide film and polysilicon on the silicon-rich silicon nitride film. Accordingly, the effect of preventing contamination of a low-pressure chemical vapor deposition (LPCVD) reactor and a wafer due to a change in gas partial pressure is expected.

Prior Patent 2 discloses calculating the weight of each layer from a target film thickness of an input D-poly film and an a-Si film, calculating activation energy of a laminated film based on the calculated weight and the activation energy, creating a laminated film model based on a relationship with temperature of each zone, calculating the optimum temperature for each zone to set the optimum temperature as a temperature of each zone, and forming the laminated film on a semiconductor wafer by controlling pressure and flow rate. Accordingly, the effect of easily adjusting heat treatment to an object to be processed is expected.

### SUMMARY

The purpose of an embodiment is to provide a substrate processing apparatus that may effectively seal a space where a heat treatment process is performed on a substrate including a semiconductor wafer.

The purpose of an embodiment is to provide a substrate processing apparatus that may efficiently and stably implement a sealed structure in a heat treatment space.

The purpose of an embodiment is to provide a substrate processing apparatus that is driven to seal a space where a heat treatment process is performed while minimizing movement of a loader accommodating a wafer.

According to an embodiment, there is provided a substrate processing apparatus for performing heat treatment on a substrate, the substrate processing apparatus including a chamber including a chamber opening through which the substrate enters or exits, a chamber upper surface on an opposite side of the chamber opening, and a chamber side surface between the chamber opening and the chamber upper surface, in which the chamber upper surface and the chamber side surface form a heat treatment space in which the substrate is accommodated, a chamber door configured to open or close the chamber opening, an outer chamber surrounding the chamber, and a locking mechanism positioned on an outer side of the chamber opening and configured to assist in locking the chamber door, in which the chamber door includes a first flange on which a substrate loader or a lower heater accommodating the substrate is placed, a rotating flange rotatably connected to the first flange, and a second flange disposed below the first flange and rotatably connected to the rotating flange.

At least a portion of the rotating flange may overlap at least a portion of the locking mechanism by rotation of the rotating flange, and the chamber door may be configured to lock the heat treatment space to be sealed.

The rotating flange may include a first rotating flange that is connected to the first flange and relatively rotatable, a second rotating flange that is connected to the second flange and relatively rotatable, and an elastic element that connects the first rotating flange to the second rotating flange and is elastically pressed, in which the first rotating flange, the second rotating flange, and the elastic element may be integrally rotatable.

A first bearing may be disposed between the first flange and the first rotating flange, and a second bearing may be disposed between the second flange and the second rotating flange.

The first rotating flange may include a first sawtooth structure protruding outwardly.

The locking mechanism may include a donut-shaped locking body and a second sawtooth structure protruding inwardly from the donut-shaped locking body, in which the first sawtooth structure may overlap the second sawtooth structure.

The substrate processing apparatus may further include an ascending and descending driver configured to ascend and descend the second flange and a rotating driver configured to rotate the second rotating flange.

The outer chamber may include an outer chamber upper surface spaced apart outwardly from the chamber upper surface, an outer chamber side surface spaced apart outwardly from the chamber side surface, and an outer chamber base on an opposite side of the outer chamber upper surface and configured to seal between the chamber side surface and the outer chamber side surface, in which the outer chamber upper surface, the outer chamber side surface, and the outer chamber base may form a sealed space between the outer chamber and the chamber.

According to an embodiment, there is provided a door part used in a semiconductor substrate processing apparatus, the door part including a first flange on which a loader accommodating a wafer is placed, a door disposed below the first flange and capable of rotating, and a second flange disposed below the door and configured to support the door, in which a heat treatment part of the semiconductor substrate processing apparatus is capable of being sealed by rotation of the door part.

The first flange and the second flange may not rotate when the door rotates.

The door may include a first connecting element disposed on an upper portion of the door and a second connecting element disposed on a lower portion of the door, in which outer surfaces of the first connecting element may be connected to each other by the first flange and a first bearing, and inner surfaces of the second connecting element may be connected to each other by the second flange and a second bearing.

A sawtooth may be formed on an outer surface of the second connecting element, and the door may be rotated by a driving element driven in engagement with the sawtooth of the second connecting element.

According to an embodiment, there is provided a semiconductor substrate processing apparatus including a chamber, a heat treatment part disposed on an upper side of the chamber and configured to perform a heat treatment process on a wafer, and a door part disposed on a lower side of the chamber and capable of moving vertically, in which an opening is formed in a lower surface of the heat treatment part, and the opening is capable of being sealed by rotation of the door part moved upwardly.

The semiconductor substrate processing apparatus may further include a guide disposed on the lower side inside the chamber, in which the guide may be formed to extend in a direction that is perpendicular to a lower surface of the chamber, and the door part may move vertically along the guide.

The guide may include a first frame extending in the direction that is perpendicular to the lower surface of the chamber and a second frame connecting the door part to the first frame and capable of moving vertically along the first frame.

The door part may include a first flange on which a loader accommodating a wafer is placed, a door disposed below the first flange and capable of rotating, and a second flange disposed below the door and configured to support the door, in which the opening of the heat treatment part may be sealed by rotation of the door, and the first flange and the second flange may not rotate when the door rotates.

The door may include a first connecting element disposed on an upper portion of the door and a second connecting element disposed on a lower portion of the door, in which outer surfaces of the first connecting element may be connected to each other by the first flange and a first bearing, inner surfaces of the second connecting element may be connected to each other by the second flange and a second bearing, and the second flange may be fixed to the second frame.

A sawtooth may be formed on an outer surface of the second connecting element, and the door may be rotated by a driving element driven in engagement with the sawtooth of the second connecting element.

Additional aspects of embodiments will be set forth in part in the description which follows and, in part, will be apparent from the description, or may be learned by practice of the disclosure.

A substrate processing apparatus according to an embodiment may effectively seal a space where a heat treatment process for a substrate is performed.

The substrate processing apparatus according to an embodiment allows the sealed structure of the heat treatment space to remain stable.

A substrate processing apparatus according to an embodiment may be driven to seal a space where a heat treatment process is performed while minimizing movement of a loader accommodating a wafer.

### BRIEF DESCRIPTION OF THE DRAWINGS

FIG. 1 illustrates a structure of a substrate processing apparatus, according to an embodiment;

FIG. 2 illustrates in detail a chamber door of the substrate processing apparatus, according to an embodiment;

FIG. 3 illustrates a driving state of the substrate processing apparatus, according to an embodiment;

FIG. 4 illustrates a cross-sectional view of the substrate processing apparatus of FIG. 3;

FIG. 5 illustrates a perspective view of a semiconductor substrate processing apparatus, according to an embodiment;

FIG. 6 illustrates the inside of the semiconductor substrate processing apparatus, according to an embodiment;

FIG. 7 illustrates a guide and a door part of the semiconductor substrate processing apparatus, according to an embodiment;

FIGS. 8 and 9 illustrate in detail the door part of the semiconductor substrate processing apparatus, according to an embodiment;

FIGS. 10 and 11 illustrate a state in which the door part of the semiconductor substrate processing apparatus is driven vertically, according to an embodiment; and

FIGS. 12A and 12B illustrate a state in which the door part of the semiconductor substrate processing apparatus rotates, according to an embodiment.

### DETAILED DESCRIPTION

Hereinafter, embodiments will be described in detail with reference to the accompanying drawings. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not to be limiting of the embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure.

In addition, terms such as first, second, A, B, (a), (b), and the like may be used to describe components of the embodiments. These terms are used only for the purpose of discriminating one component from another component, and the nature, the sequences, or the orders of the components are not limited by the terms. It should be noted that if one component is described as being “connected,” “coupled” or “joined” to another component, the former may be directly “connected,” “coupled,” and “joined” to the latter or “connected”, “coupled”, and “joined” to the latter via another component.

The same name may be used to describe an element included in the embodiments described above and an element having a common function. Unless otherwise mentioned, the descriptions on the embodiments may be applicable to the following embodiments and thus, duplicated descriptions will be omitted for conciseness.

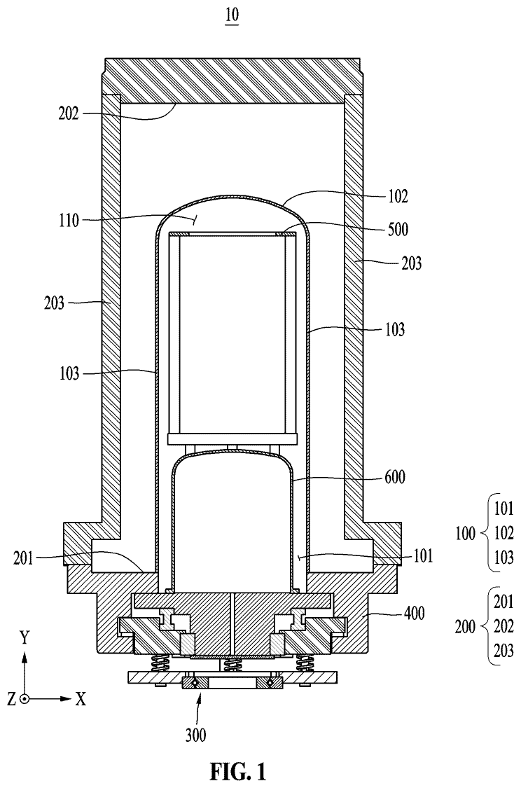

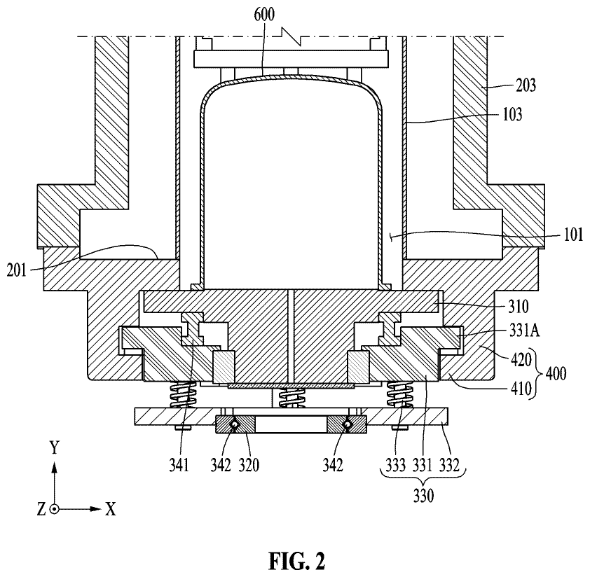

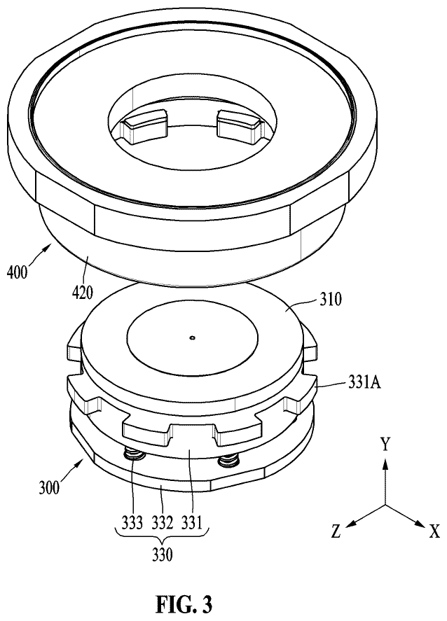

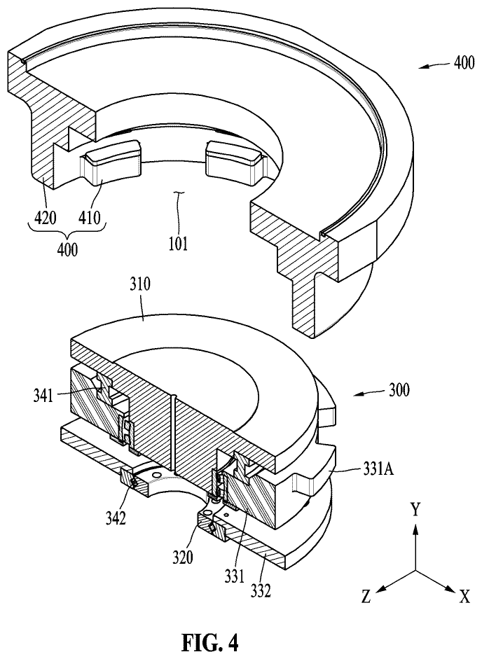

FIG. 1 illustrates a structure of a substrate processing apparatus 10, according to an embodiment. FIG. 2 illustrates in detail a chamber door 300 of the substrate processing apparatus 10, according to an embodiment. FIG. 3 illustrates a driving state of the substrate processing apparatus 10, according to an embodiment. FIG. 4 illustrates a cross-sectional view of the substrate processing apparatus 10 of FIG. 3.

Referring to FIGS. 1 to 4, the substrate processing apparatus 10 according to an embodiment may include a chamber 100, an outer chamber 200, the chamber door 300, and a locking mechanism 400.

In an embodiment, the chamber 100 may include a chamber opening 101 through which a substrate enters or exits, a chamber upper surface 102 on the opposite side of the chamber opening 101, and a chamber side surface 103 between the chamber opening 101 and the chamber upper surface 102.

The chamber 100 may include a heat treatment space 110 defined by the chamber opening 101, the chamber upper surface 102, and the chamber side surface 103. The substrate may be accommodated in the heat treatment space 110, and heat treatment may be performed on the substrate at a high temperature and/or high pressure in the heat treatment space 110. A heating portion that heats the chamber 100 may be disposed on the outer side of the chamber 100. An inlet or outlet for substrate processing gas (e.g., hydrogen, deuterium, etc.) communicating with the heat treatment space 110 may be formed in at least one of the chamber upper surface 102 and the chamber side surface 103 of the chamber 100.

The chamber opening 101 may be implemented as an opening through which the substrate enters or exits. For example, in FIG. 1, the chamber opening 101 may be formed in the lower portion of the chamber 100 (e.g., the side in the −Y direction of FIG. 1), and the chamber opening 101 may be closed by the chamber door 300.

In an embodiment, the chamber door 300 may be disposed on the lower portion of the chamber opening 101 (e.g., the side of the chamber opening 101 of FIG. 1 in the −Y direction). The chamber door 300 may move forward or backward to or from the chamber opening 101. For example, when the chamber 100 and the chamber door 300 are placed perpendicular in the direction of gravity, the chamber door 300 may ascend or descend toward or from the chamber opening 101.

A substrate loader 500 and/or a lower heater 600 may be disposed on the upper side of the chamber door 300 (e.g., the side in the +Y direction of FIG. 1). For example, the lower heater 600 may be disposed between the chamber door 300 and the substrate loader 500.

For example, the chamber door 300, the substrate loader 500, and the lower heater 600 may be integrally coupled. The chamber door 300, the substrate loader 500, and the lower heater 600 may ascend and descend together to and from the chamber opening 101. In another example, the chamber door 300 may be provided separately from the substrate loader 500 and the lower heater 600.

In particular, referring to FIG. 3 or FIG. 4, as the chamber door 300 ascends toward the chamber opening 101 (e.g., as the chamber door 300 moves forward in the +Y direction of FIG. 3 or FIG. 4), the heat treatment space 110 may be sealed when the chamber door 300 completely closes the chamber opening 101. A heat treatment process may be performed on the substrate while the substrate is accommodated in the sealed heat treatment space 110. In contrast, the chamber opening 101 may be opened when the chamber door 300 descends from the chamber opening 101 (e.g., when the chamber door 300 moves backward in the −Y direction of FIG. 3 or FIG. 4). The substrate loader 500 and the lower heater 600 may exit the heat treatment space 110. The substrate on which the heat treatment process is completed may move to a stage for the next process.

The chamber door 300 may ascend and descend along a guide, and the guide may include a frame extending in the vertical direction (e.g., +/ −Y direction in FIG. 3 or FIG. 4).

Referring back to FIGS. 1 and 2, in an embodiment, the outer chamber 200 may include an outer chamber upper surface 202 spaced apart outwardly from the chamber upper surface 102, an outer chamber side surface 203 spaced apart outwardly from the chamber side surface 103, and an outer chamber base 201 on the opposite side of the outer chamber upper surface 202 and sealing between the chamber side surface 103 and the outer chamber side surface 203.

The outer chamber upper surface 202, the outer chamber side surface 203, and the outer chamber base 201 may surround the outer side of the chamber 100, and the chamber 100 may be placed in a completely sealed space by the outer chamber upper surface 202, the outer chamber side surface 203, the outer chamber base 201, and the chamber door 300. The space sealed by the outer chamber upper surface 202, the outer chamber side surface 203, the outer chamber base 201, and the chamber door 300 may be defined as an outer space, and since the outer space surrounds the chamber 100, predetermined external pressure may be applied to the outer side of the chamber 100. When first pressure is applied to the heat treatment space 110, second pressure corresponding to the first pressure may be applied to the outer space, and through this, large force may not be applied to the chamber upper surface 102 and the chamber side surface 103 so that the chamber 100 may stably maintain its form even when high pressure is applied to the heat treatment space 110 of the chamber 100. The outer chamber 200 and the chamber door 300 may be made of a material with higher hardness and/or strength than the chamber 100.

In an embodiment, an inlet or outlet for inert gas (e.g., nitrogen, argon, etc.) flowing into the outer space may be formed in at least one of the outer chamber upper surface 202 and the outer chamber side surface 203 of the outer chamber 200. A heating portion that heats the outer space may be disposed in the outer chamber 200. Alternatively, the heating portion that heats the outer space may be disposed outside of the outer chamber 200 and adjacent to the outer chamber 200.

In an embodiment, the outer chamber base 201 may be coupled to a housing forming the outer chamber side surface 203. The outer chamber base 201 may be bolt-coupled to the housing forming the outer chamber side surface 203. The rigid coupling of the outer chamber base 201 may allow the outer space to be maintained even in a high-pressure environment.

In an embodiment, the outer chamber base 201 may be implemented in the form of a flange extending outwardly from the lower end of the chamber side surface 103.

In an embodiment, the substrate processing apparatus 10 may further include a locking mechanism 400 for locking the chamber door 300. The chamber door 300 and the locking mechanism 400 may perform a locking function to maintain the heat treatment space 110 in a sealed state.

In particular, referring to FIGS. 2 to 4, the chamber door 300 may include a first flange 310 on which the substrate loader 500 accommodating the substrate or the lower heater 600 is placed, a rotating flange 330 rotatably connected to the first flange 310, and a second flange 320 disposed on the lower side (e.g., the side in the-Y direction in FIGS. 2 to 4) of the first flange 310 and rotatably connected to the first flange 310.

The chamber door 300 may be locked as at least a portion of the rotating flange 330 overlaps at least a portion of the locking mechanism 400 through the rotation of the rotating flange 330.

The rotating flange 330 may include a first rotating flange 331 that is connected to the first flange 310 and relatively rotatable, a second rotating flange 332 that is connected to the second flange 320 and relatively rotatable, and an elastic element 333 that connects the first rotating flange 331 to the second rotating flange 332 and elastically pressed. The first rotating flange 331, the second rotating flange 332, and the elastic element 333 may be integrally coupled and may rotate together.

In an embodiment, a first bearing 341 may be inserted between the first flange 310 and the first rotating flange 331, and a second bearing 342 may be inserted between the second flange 320 and the second rotating flange 332.

The first rotating flange 331 may include a first sawtooth structure 331A protruding outwardly. The locking mechanism 400 may include a donut-shaped locking body 420 and a second sawtooth structure 410 protruding inwardly from the donut-shaped locking body 420. The first sawtooth structure 331A may overlap the second sawtooth structure 410. For example, when viewed in the +/−Y direction in FIGS. 2 to 4, the first sawtooth structure 331A may overlap the second sawtooth structure 410 due to the rotation of the first rotating flange 331.

The first flange 310 may include a disk-shaped structure and may have a size capable of closing the chamber opening 101. The first rotating flange 331 may be connected to the first flange 310 by the first bearing 341 and be relatively rotatable. For example, the first flange 310 may include a disk-shaped upper structure and a pillar structure extending downward from the disk-shaped upper structure and may have a “T”-shaped cross-section. The first rotating flange 331 may have a donut-shaped structure surrounding the pillar structure of the first flange 310. At least one bearing (e.g., the first bearing 341) may be inserted between the inside of the first rotating flange 331 and the pillar structure of the first flange 310.

The second rotating flange 332 may be disposed spaced apart downward from the first rotating flange 331, and the elastic element 333 may be disposed between the first rotating flange 331 and the second rotating flange 332. For example, the elastic element 333 may be a coil spring. A guide bar connecting the first rotating flange 331 to the second rotating flange 332 may be provided, and the coil spring may be disposed to surround the guide bar. The first rotating flange 331 may be pressed in the upward direction (e.g., +Y direction in FIGS. 2 to 4) by the elastic element 333. For example, pressure may be applied in the upward direction of the first flange 310 by the elastic element 333 when the first flange 310 ascends to the chamber opening 101.

The second rotating flange 332 may have a donut-shaped structure, and the second flange 320 may be disposed inside the second rotating flange 332. At least one bearing (e.g., the second bearing 342) may be inserted between the inside of the second rotating flange 332 and the second flange 320.

Since the substrate loader 500 or the lower heater 600 may sit on the first flange 310, it may be preferable that the first flange 310 does not rotate. In contrast, the rotating flange 330 may need to rotate to perform the locking function with the locking mechanism 400. According to an embodiment, the first bearing 341 and/or the second bearing 342 may allow the rotation of only the rotating flange 330 without the first flange 310 and the second flange 320 rotating when the chamber door 300 seals the heat treatment space 110.

The first sawtooth structure 331A may include regularly arranged teeth protruding to the outside of the first rotating flange 331. For example, the first sawtooth structure 331A may include regularly arranged protrusions protruding from the first rotating flange 331 with a disk shape. The first rotating flange 331 may rotate with the Y-axis of FIGS. 2 to 4 as the central axis. The first sawtooth structure 331A may also be rotated by the rotation of the first rotating flange 331.

The first sawtooth structure 331A and the second sawtooth structure 410 may be placed at positions that do not overlap each other in the vertical direction when the chamber door 300 does not seal the chamber opening 101. For example, when viewed in the Y-axis direction in FIGS. 2 to 4, the first sawtooth structure 331A may not overlap the second sawtooth structure 410.

When the chamber door 300 ascends toward the chamber opening 101 and seals the chamber opening 101, the first rotating flange 331 may rotate and the first sawtooth structure 331A may also rotate along therewith. The first rotating flange 331 may rotate until at least a portion of the first sawtooth structure 331A overlaps the second sawtooth structure 410. For example, when viewed in the Y-axis direction in FIGS. 2 to 4, at least a portion of the first sawtooth structure 331A may overlap at least a portion of the second sawtooth structure 410.

Due to the overlap of the first sawtooth structure 331A and the second sawtooth structure 410, the chamber door 300 may be stably maintained in place without escaping from the position where the chamber opening 101 is sealed, and through this, the heat treatment space 110 may be stably sealed.

The substrate processing apparatus 10 according to an embodiment may further include an ascending and descending driver (e.g., a cylinder, motor, etc.) for ascending and descending the second flange 320 and a rotating driver (e.g., a cylinder, motor, ball screw, etc.) for rotating the second rotating flange 332.

The substrate processing apparatus 10 according to an embodiment may effectively seal the heat treatment space 110 in which the heat treatment process is performed on the substrate, and the sealing of the heat treatment space 110 may be stably maintained during the heat treatment of the substrate.

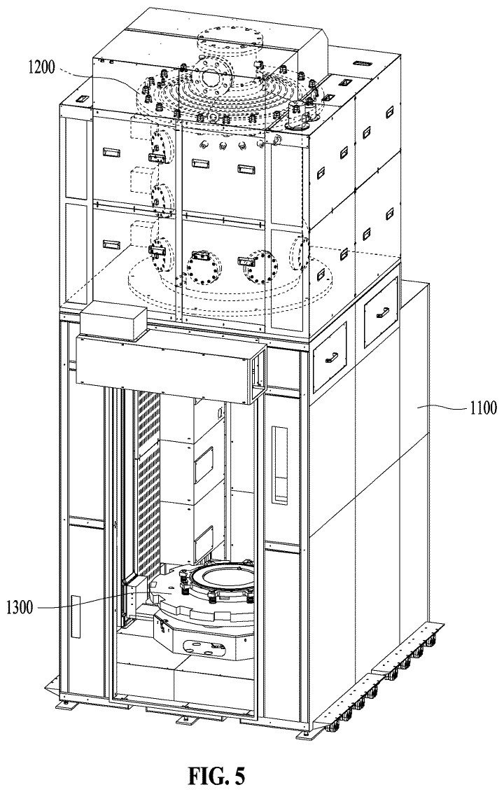

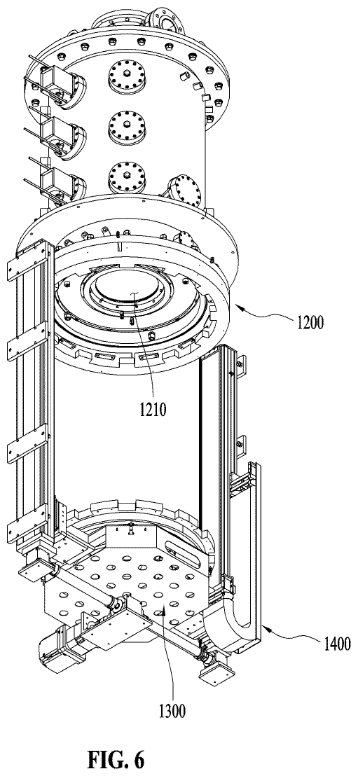

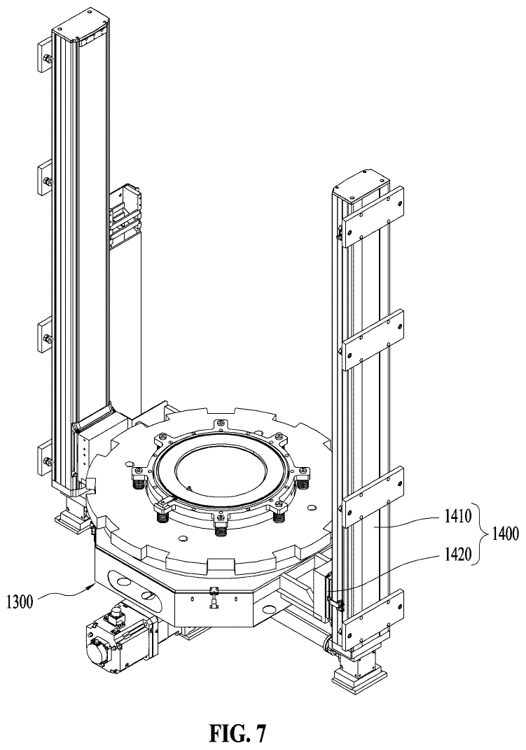

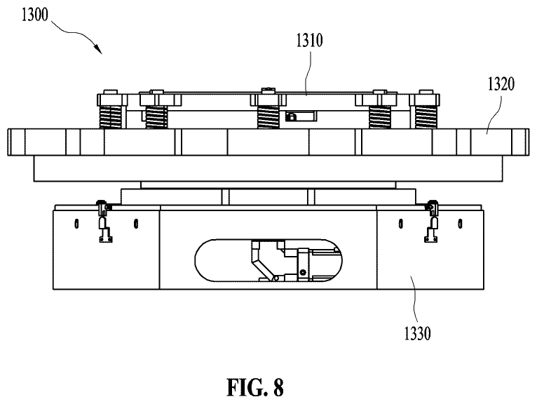

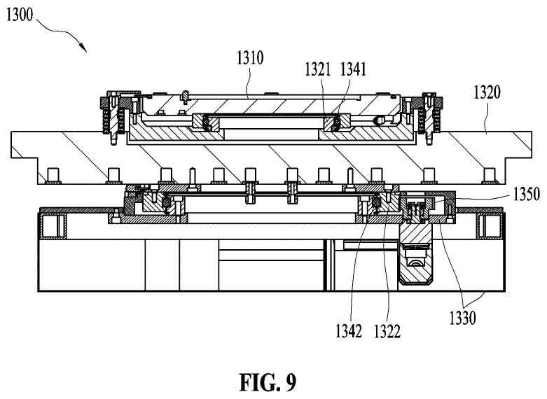

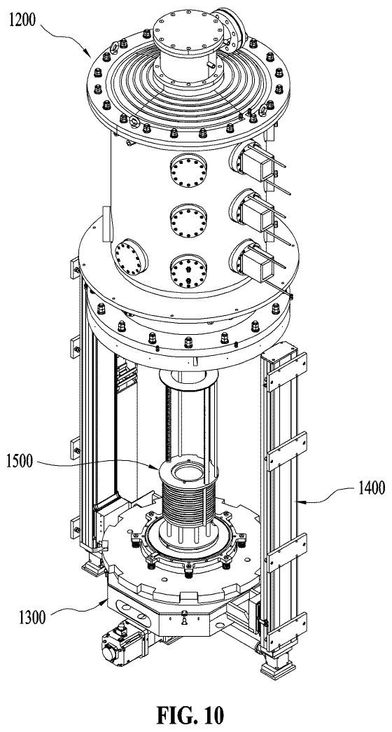

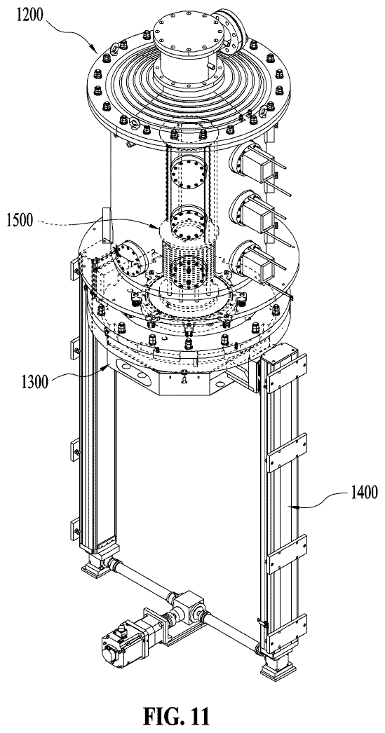

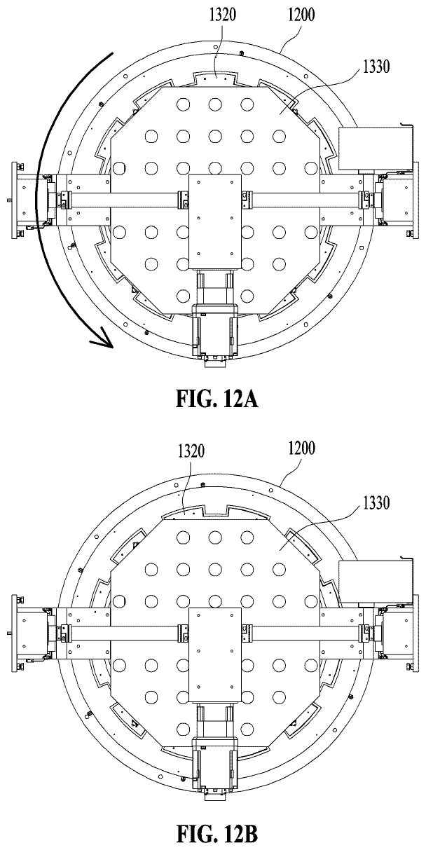

FIG. 5 illustrates a perspective view of a semiconductor substrate processing apparatus, according to an embodiment, and FIG. 6 illustrates the inside of the semiconductor substrate processing apparatus, according to an embodiment. FIG. 7 illustrates a guide and a door part of the semiconductor substrate processing apparatus, according to an embodiment, and FIGS. 8 and 9 illustrate in detail the door part of the semiconductor substrate processing apparatus, according to an embodiment. FIGS. 10 and 11 illustrate a state in which the door part of the semiconductor substrate processing apparatus is driven vertically, according to an embodiment, and FIGS. 12A and 12B illustrate a state in which the door part of the semiconductor substrate processing apparatus rotates, according to an embodiment.

Referring to FIGS. 5 to 8, the semiconductor substrate processing apparatus according to an embodiment may include a chamber 1100, a heat treatment part 1200 disposed on the upper side of the chamber 1100 and performing a heat treatment process on a wafer, a door part 1300 disposed on the lower side of the chamber 1100 and capable of moving vertically, and a guide 1400 disposed on the lower side inside the chamber 1100.

Here, when the door part 1300 is disposed on the lower end of the chamber 1100, a loader 1500 that enters through an opening element formed in one surface of the chamber 1100 may be disposed on the upper side of the door part 1300, and then the loader 1500 may be accommodated in the heat treatment part 1200 as the door part 1300 moves to the upper side of the chamber 1100 along the guide 1400.

For this driving, an opening 1210 may be formed in the lower surface of the heat treatment part 1200, and the opening 1210 may be sealed by the rotation of the door part 1300 moved upwardly. A driving mechanism of the semiconductor substrate processing apparatus is described in more detail below.

The guide 1400 may be formed to extend from the inside of the chamber 1100 in a direction that is perpendicular to the lower surface of the chamber 1100, and the door part 1300 may move vertically along the guide 1400.

Specifically, the guide 1400 may include a first frame 1410 and a second frame 1420, the first frame 1410 may extend in a direction that is perpendicular to the lower surface of the chamber 1100, and the second frame 1420 may move vertically along the first frame 1410.

That is, the door part 1300 may be connected to the first frame 1410 by the second frame 1420 and may move vertically inside the chamber 1100 along a path guided by the first frame 1410. Accordingly, a portion of the door part 1300 may be disposed inside the heat treatment part 1200 when the door part 1300 is completely moved to the upper side of the chamber 1100 along the first frame 1410.

Thereafter, as the door part 1300 rotates, the heat treatment part 1200 may be sealed, and, in this case, only a door 1320, which is one component of the door part 1300, may rotate independently. Hereinafter, a driving mechanism of the door part 1300 is described in detail.

Referring to FIGS. 8 and 9, the door part 1300 may include a first flange 1310 on which the loader 1500 accommodating a wafer is placed, the door 1320 disposed below the first flange 1310 and capable of rotating, and a second flange 1330 disposed below the door 1320 and supporting the door 1320. Here, the door 1320 may rotate, but the first flange 1310 and the second flange 1330 may not rotate. That is, only the door 1320 rotates independently to seal the opening 1210 of the heat treatment part 1200, and the first flange 1310 supporting the loader 1500 accommodating the wafer may maintain a first set state without rotating, thereby stably maintaining the disposition state of the wafer for heat treatment.

For this driving, the door 1320 may include a first connecting element 1321 disposed on the upper portion of the door 1320 and a second connecting element 1322 disposed on the lower portion of the door 1320, and the outer surfaces of the first connecting element 1321 may be connected to each other by the first flange 1310 and a first bearing 1341, and the inner surfaces of the second connecting element 1322 may be connected to each other by the second flange 1330 and a second bearing 1342.

In addition, a sawtooth may be formed on the outer surface of the second connecting element 1322, and the door 1320 may be rotated by a driving element 1350 driven in engagement with the sawtooth of the second connecting element 1322.

That is, the rotational force generated by the driving element 1350 may be transmitted to the second connecting element 1322 of the door 1320 so that the door 1320 itself may rotate when the driving element 1350, which may be driven by an element such as a sub motor, rotates.

Here, the second flange 1330 may be fixed to the second frame 1420 of the guide 1400. Accordingly, the second flange 1330 may be fixed without rotating even when the door 1320 is rotated by the driving element 1350. That is, even when the door 1320 is rotated by the second bearing 1342, separate frictional force may not be generated between the second flange 1330 and the door 1320, so the second flange 1330 may be maintained in a fixed state, and only the door 1320 may rotate.

In addition, when the loader 1500 is placed on the first flange 1310, the first flange 1310 may also be fixed without rotating due to the load applied downward by the loader 1500, and even when the door 1320 is rotated by the first bearing 1341, separate frictional force may not be generated between the first flange 1310 and the door 1320, so the first flange 1310 may be maintained in a fixed state, and only the door 1320 may rotate.

However, embodiments are not necessarily limited thereto, and similar to the second flange 1330, the first flange 1310 may also be fixed without rotating by being separately fixed to another component disposed outside of the first flange 1310.

The driving mechanism of the semiconductor substrate processing apparatus including the components described above is described in more detail below.

Referring to FIG. 10, when the door part 1300 moves to the lower side inside the chamber 1100 and disposed along the guide 1400, the loader 1500 on which the wafer is loaded may be inserted into the chamber 1100 through the opening element formed in one surface of the chamber 1100 and then may be placed on the upper surface of the door part 1300. More precisely, the loader 1500 may be placed on the first flange 1310 of the door part 1300.

Thereafter, as shown in FIG. 11, the loader 1500 may be disposed in the heat treatment part 1200 when the door part 1300 moves upward in the chamber 1100 along the guide 1400. Thereafter, as the door 1320 of the door part 1300 rotates, the heat treatment part 1200 may be sealed, and the heat treatment process may be stably performed on the wafer in the heat treatment part 1200.

Referring to FIG. 12, protrusions formed to be spaced apart at regular intervals may be disposed on the outer circumferential surface of the door 1320 of the door part 1300. In addition, grooves may be formed in a shape corresponding to the protrusions of the door 1320 along the inner circumferential surface of an opening of the heat treatment part 1200. Accordingly, as shown FIG. 12A, the protrusions of the door 1320 may pass through the grooves of the opening and may move to the inside of the heat treatment part 1200 when the door part 1300 moves upwardly from the inside of the chamber 1100. Afterwards, as shown in FIG. 12B, the door 1320 may rotate inside the heat treatment part 1200, and the heat treatment part 1200 may be sealed.

While the embodiments are described with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order, and/or if components in a described system, architecture, device, or circuit are combined in a different manner, or replaced or supplemented by other components or their equivalents.

Therefore, other implementations, other embodiments, and equivalents to the claims are also within the scope of the following claims.

1. A substrate processing apparatus for performing heat treatment on a substrate, the substrate processing apparatus comprising:
a chamber comprising a chamber opening through which the substrate enters or exits, a chamber upper surface on an opposite side of the chamber opening, and a chamber side surface between the chamber opening and the chamber upper surface, wherein the chamber upper surface and the chamber side surface form a heat treatment space in which the substrate is accommodated;
a chamber door configured to open or close the chamber opening;
an outer chamber surrounding the chamber; and
a locking mechanism positioned on an outer side of the chamber opening and configured to assist in locking the chamber door,
wherein the chamber door comprises:
a first flange on which a substrate loader or a lower heater accommodating the substrate is placed;
a rotating flange rotatably connected to the first flange; and
a second flange disposed below the first flange and rotatably connected to the rotating flange.

2. The substrate processing apparatus of claim 1, wherein at least a portion of the rotating flange overlaps at least a portion of the locking mechanism by rotation of the rotating flange, and the chamber door is configured to lock the heat treatment space to be sealed.

3. The substrate processing apparatus of claim 1, wherein the rotating flange comprises:
a first rotating flange that is connected to the first flange and relatively rotatable;
a second rotating flange that is connected to the second flange and relatively rotatable; and
an elastic element that connects the first rotating flange to the second rotating flange and is elastically pressed,
wherein the first rotating flange, the second rotating flange, and the elastic element are integrally rotatable.

4. The substrate processing apparatus of claim 3, wherein a first bearing is disposed between the first flange and the first rotating flange, and a second bearing is disposed between the second flange and the second rotating flange.

5. The substrate processing apparatus of claim 3, wherein the first rotating flange comprises a first sawtooth structure protruding outwardly.

6. The substrate processing apparatus of claim 5, wherein the locking mechanism comprises:
a donut-shaped locking body; and
a second sawtooth structure protruding inwardly from the donut-shaped locking body,
wherein the first sawtooth structure is capable of overlapping the second sawtooth structure.

7. The substrate processing apparatus of claim 6, further comprising:
an ascending and descending driver configured to ascend and descend the second flange; and
a rotating driver configured to rotate the second rotating flange.

8. The substrate processing apparatus of claim 1, wherein the outer chamber comprises:
an outer chamber upper surface spaced apart outwardly from the chamber upper surface;
an outer chamber side surface spaced apart outwardly from the chamber side surface; and
an outer chamber base on an opposite side of the outer chamber upper surface and configured to seal between the chamber side surface and the outer chamber side surface,
wherein the outer chamber upper surface, the outer chamber side surface, and the outer chamber base form a sealed space between the outer chamber and the chamber.

9. A door part used in a semiconductor substrate processing apparatus, the door part comprising:
a first flange on which a loader accommodating a wafer is placed;
a door disposed below the first flange and capable of rotating; and
a second flange disposed below the door and configured to support the door,
wherein a heat treatment part of the semiconductor substrate processing apparatus is capable of being sealed by rotation of the door part.

10. The door part of claim 9, wherein the first flange and the second flange do not rotate when the door rotates. 11 The door part of claim 10, wherein the door comprises:
a first connecting element disposed on an upper portion of the door; and
a second connecting element disposed on a lower portion of the door,
wherein outer surfaces of the first connecting element are connected to each other by the first flange and a first bearing, and
wherein inner surfaces of the second connecting element are connected to each other by the second flange and a second bearing.

12. The door part of claim 11, wherein a sawtooth is formed on an outer surface of the second connecting element, and the door is capable of being rotated by a driving element driven in engagement with the sawtooth of the second connecting element.

13. A semiconductor substrate processing apparatus comprising:
a chamber;
a heat treatment part disposed on an upper side of the chamber and configured to perform a heat treatment process on a wafer; and
a door part disposed on a lower side of the chamber and capable of moving vertically,
wherein an opening is formed in a lower surface of the heat treatment part, and the opening is capable of being sealed by rotation of the door part moved upwardly.

14. The semiconductor substrate processing apparatus of claim 13, further comprising:
a guide disposed on the lower side inside the chamber,
wherein the guide is formed to extend in a direction that is perpendicular to a lower surface of the chamber, and
wherein the door part is capable of moving vertically along the guide.

15. The semiconductor substrate processing apparatus of claim 14, wherein the guide comprises:
a first frame extending in the direction that is perpendicular to the lower surface of the chamber; and
a second frame connecting the door part to the first frame and capable of moving vertically along the first frame.

16. The semiconductor substrate processing apparatus of claim 15, wherein the door part comprises:
a first flange on which a loader accommodating a wafer is placed;
a door disposed below the first flange and capable of rotating; and
a second flange disposed below the door and configured to support the door,
wherein the opening of the heat treatment part is capable of being sealed by rotation of the door, and
wherein the first flange and the second flange do not rotate when the door rotates.

17. The semiconductor substrate processing apparatus of claim 16, wherein the door comprises:
a first connecting element disposed on an upper portion of the door; and
a second connecting element disposed on a lower portion of the door, wherein outer surfaces of the first connecting element are connected to each other by the first flange and a first bearing,
wherein inner surfaces of the second connecting element are connected to each other by the second flange and a second bearing, and
wherein the second flange is fixed to the second frame.

18. The semiconductor substrate processing apparatus of claim 17, wherein a sawtooth is formed on an outer surface of the second connecting element, and the door is capable of being rotated by a driving element driven in engagement with the sawtooth of the second connecting element.
